(19) United States
(12) Patent Application Publication
(10) Pub. No.: US 2026/0045930 A1
(43) Pub. Date: Feb. 12, 2026

(54) Thin Film Bulk Acoustic FBAR Resonator With Spurious Mode Suppression Mechanism

(71) Applicant: Changzhou Crystal Resonance Technologies Co., Ltd., CHANGZHOU (CN)

(72) Inventors: Dror HURWITZ, CHANGZHOU (CN); Yuan Yuan, CHANGZHOU (CN)

(73) Assignee: Changzhou Crystal Resonance Technologies Co., Ltd., CHANGZHOU (CN)

(21) Appl. No.: 18/805,303

(22) Filed: Aug. 14, 2024

(30) Foreign Application Priority Data
Aug. 8, 2024 (CN) 202411019276.4

(51) Int. Cl. H03H 9/13; H03H 9/17; H03H 9/64

(52) U.S. Cl. CPC H03H 9/132; H03H 9/173; H03H 9/6469

(57) ABSTRACT

A mechanism for suppression of spurious signals or modes in FBAR resonators and filters, incorporating the effects of the electromagnetic (EM) cavity resonance physical field model. The suppression of spurious signals is achieved by modifying the characteristics of the EM cavity resonance of the FBAR resonator. This is achieved by keeping the fundamental piezoelectric resonance frequency of the resonator constant and shifting the EM cavity resonance to a lower frequency. This shift of the EM cavity resonance frequency ensures that the sub-spurious signals generated from the interaction between the piezoelectric resonance frequency and the EM cavity resonance frequency, are shifted to a lower-frequency, which advantageously lies in a rejection band area outside the passband of the piezoelectric resonance. The FBAR resonator is modified to include a “zipper” edge top electrode which includes a series of local ridges or peaks and valleys being generally between adjacent ridges or peaks.

### CROSS REFERENCE TO RELATED APPLICATIONS

Applicant claims priority and the benefit of CN application No. 202411019276.4, filed Aug. 8, 2024, the disclosure of which is incorporated herein by reference.

### BACKGROUND OF THE INVENTION

Due to rapid advances in cellular telephony, satellite communications, and other types of wireless communication systems, filters have become an important part of such devices in order to prevent interference between different types of communication systems. However, traditional radiofrequency (RF) filters cannot meet the demands of miniaturization and high frequency operation required in modern communication systems, owing to their relatively large size and power consumption demands.

A Thin Film Bulk Acoustic Resonator (FBAR) is typically an acoustically isolated device which includes a piezoelectric thin film material sandwiched between two electrodes, formed on a semiconductor substrate, such as silicon (Si) or gallium arsenide (GaAs). A resonance is induced owing to the piezoelectric properties of the thin film. Commonly used FBAR resonators utilize piezoelectric films which have a thickness ranging from several microns down to a tenth of a micron, and resonate in a frequency range of roughly 100 MHz to 10 GHz. Commonly used materials for the piezoelectric film include aluminum nitride and zinc oxide. Aluminum nitride is advantageous in that it provides low acoustic attenuation and stable chemical properties, while providing high velocity and a fabrication process that is compatible with existing complementary metal-oxide semiconductor (CMOS) fabrication processes.

FBAR resonator devices can be miniaturized to have a size which is less than 1% of the size of a corresponding dielectric filter or an LC filter, and may have an insertion loss which is less than half of a surface acoustic wave (SAW) device.

One application or use of FBAR resonators is in RF filters which are used in cellular phones and other wireless devices. These filters are typically constructed using a number of resonators and are designed to remove unwanted frequencies, while allowing frequencies of interest to be transmitted and received. FBAR resonators may also be used in sensor applications where a device is subject to some type of mechanical force which causes its resonance frequency to shift.

FBAR filters possess excellent frequency selectivity and filtering performance, enabling high-quality signal filtering and facilitating high-speed data transmission and spectrum efficiency for next-generation RF networks. FBAR filters can achieve miniaturization and integration, improving next-generation communication systems integration and performance density and bringing new application scenarios and possibilities. They are increasingly used in various fields, such as Advanced smartphones, Internet of Things (IoT) devices, satellite communication, connected vehicles, and industrial automation.

The vibrating membrane Resonators are the foundation of FBAR filters. When a standard FBAR filter resonates, there are often spurious signals or modes within or near the low-frequency portion of the series resonance frequency Fs, which significantly affect the performance of FBAR filters incorporating such resonators. In an FBAR resonator, the resonance frequency, F₀, is the frequency at which the impedance of the resonator is at a minimum. At F₀, the inductive reactance and capacitive reactance cancel each other out, resulting in maximum admittance (minimum impedance). It is also known as the fundamental resonant frequency. Fₛ is the series resonant frequency, and is typically the same as F₀.

This distortion due to the spurious modes leads to passband losses and might even cause the FBAR filter to fail. Therefore, effectively suppressing resonant spurious signals is an important objective for the proper operation of an FBAR filter.

Piston mode, often referred to as the fundamental thickness extensional mode, is the desired mode of vibration in FBAR devices. In this mode, the entire resonator's thickness oscillates uniformly. The vibration is primarily in the direction perpendicular to the plane of the resonator, resulting in efficient energy conversion and minimal energy loss. Spurious modes or signals are unwanted vibration modes that can occur at frequencies other than the fundamental mode. These modes, including lateral modes, arise due to various factors such as non-uniformities in the resonator structure. Spurious modes can degrade the performance of the FBAR by introducing additional resonances, which can lead to increased insertion loss, reduced filter selectivity, and potential interference in the frequency response.

The mechanism causing spurious signals in the FBAR resonators is traditionally believed to be the effect of lateral resonances. Resonator resonances refer to the various resonance modes that can occur in the FBAR resonator. More specifically, lateral resonance refers to the condition where vibrations occur parallel to the plane of the resonator. Further, piston resonance in FBARs refers to the condition where the entire cross-section of the thin piezoelectric film vibrates uniformly in the thickness direction. This uniform vibration is similar to the movement of a piston in an engine, where the entire surface moves in phase without any significant deformation across the surface. Piston resonance results in high-quality factors (Q-factors), and reduces the occurrence of spurious modes and mode splitting, leading to a more stable and predictable frequency response. Mode splitting refers to the phenomenon where the fundamental thickness extensional mode (piston mode) is not a single frequency, but splits into multiple closely spaced frequencies of piston mode and spurious modes.

Apart from the primary piston resonance excited by the FBAR electrodes, resonator resonances may also occur due to discontinuities in acoustic impedance at the edges of the resonator electrodes and the edge of the air-crystal resonance region. The air-crystal resonance region occurs when the acoustic waves generated in the piezoelectric film interact with the air or vacuum in the cavity beneath the membrane. The air-crystal resonance region is a frequency band where the acoustic waves generated by the piezoelectric layer couple with the surrounding air, leading to distinct resonance characteristics. This region is characterized by the interplay between the acoustic impedance of the piezoelectric material and that of the air, affecting the energy transmission and reflection at the resonator's surfaces.

The presence of air can cause shifts in the resonant frequencies and potentially split the primary piston mode into multiple modes due to additional boundary conditions. In practice, imperfections can cause the primary piston mode to split into multiple closely spaced resonances, resulting in unwanted resonances that can appear at frequencies other than the primary piston mode due to lateral modes. This interaction can modify the resonance characteristics of the FBAR, affecting its frequency response and overall performance.

In the air-crystal resonance region, the acoustic impedance mismatch between the piezoelectric material and the air or vacuum cavity, can make the acoustic waves reflect at the interface between the piezoelectric film and the air/vacuum cavity, creating standing wave patterns and affecting the resonance conditions. The interaction with the air or vacuum can cause shifts in the resonance frequency of the FBAR, potentially affecting the Q-factor of the resonance, and could lead to coupling between different resonance modes, potentially creating complex resonance patterns and spurious modes.

Lateral resonances are generally considered the main cause of spurious signals in FBAR resonators. Therefore, efforts are being made to suppress or eliminate lateral resonances by introducing raised structured frames, air rings, or air bridges at the resonator's electrode edges. Besides potentially increasing the parallel impedance of the resonator, these structures may also partially suppress lateral resonances, thereby suppressing spurious signals to some extent.

However, introducing raised frames, air rings, or air bridges may lead to the generation of multimodal resonances in the FBAR resonator, and the interaction between multimodal resonance reactance is extremely complex. Multimodal resonances refer to the presence of multiple vibrational modes within the device, each resonating at different frequencies. These modes include the primary piston mode and various spurious modes. Lateral mode is one of the spurious modes, where vibrations occur parallel to the plane of the resonator. Raised frames, air rings, and air bridges alter the mechanical boundary conditions of the resonator. These structures introduce additional mechanical constraints and discontinuities, which can cause the resonator to support multiple vibrational modes. Instead of vibrating uniformly, the resonator can exhibit complex vibrational patterns with different resonant frequencies.

The presence of these structures can cause reflections and scattering of acoustic waves within the resonator. The interference between the incident and reflected waves can create standing wave patterns that correspond to different resonant modes. Each mode will have its own characteristic frequency, leading to multiple resonant peaks. Raised frames, air rings, and air bridges can couple different modes of vibration, such as longitudinal, shear, and transverse modes. This coupling can lead to energy transfer between modes, further enhancing the multimodal response. As a result, the resonator can exhibit resonances at frequencies corresponding to each of these coupled modes.

These structures can also introduce localized resonances where certain parts of the resonator vibrate at different frequencies than the rest of the resonator. For example, air rings and air bridges can create localized regions with distinct resonant behavior. These localized resonances contribute to the overall multimodal resonance spectrum of the FBAR. The introduction of raised frames, air rings, or air bridges changes the geometry and material distribution within the resonator. These discontinuities can support additional resonant modes that would not be present in a uniform resonator. Each geometric feature can act as a separate resonator, with its own set of resonant frequencies.

Additionally, introducing raised frames, air rings, or air bridges will result in an acoustic impedance mismatch between the piezoelectric material and the air or vacuum cavity, which can make the acoustic waves reflect at the interface between the piezoelectric film and the air/vacuum cavity, creating standing wave patterns and affecting the resonance conditions. The interaction with the air or vacuum could lead to coupling between different resonance modes, potentially creating complex resonance patterns and spurious modes, which are referred to as “multimodal resonances”

Currently, there is no reliable multi-physics model to describe this interaction accurately, and it can only be characterized through accumulated experimental and empirical data during the production process. In practical applications, achieving effective suppression of spurious signals in the FBAR resonator and thus the corresponding filter requires higher precision microfabrication equipment and process control, as well as multiple iterations of production preparation for each frequency band and FBAR filter design. However, for UHF (Ultra High Frequency) FBAR products above 5 GHz, the implementation cost is higher, the difficulty is greater, and the yield is lower, which has become a bottleneck in optimizing and producing the FBAR filters, limiting their rapid development and time-to-market goals.

Additionally, raised frames introduce other spurious signals in the low-frequency range of the FBAR resonator resonance, which partially affects the overall performance of the FBAR filter and limits its widespread use in advanced communication systems. Therefore, the FBAR filter industry is in need of a better solution for effectively suppressing spurious signals in FBAR Resonators and Filters.

### SUMMARY OF THE INVENTION

In an embodiment, the present invention relates to a mechanism for suppression of spurious signals or modes in FBAR resonators and filters, especially for UHF products above 5 GHZ, incorporating the effects of the electromagnetic (EM) cavity resonance physical field model. EM cavity resonance refers to the resonant modes of the electromagnetic fields in the cavity surrounding the FBAR, which can couple with the acoustic resonances of the device. When an RF signal is applied to the FBAR, it not only generates acoustic waves but also creates electromagnetic (EM) fields. These EM fields can resonate within the cavity or the surrounding structure, and interact with the acoustic resonance, leading to complex coupling effects that influence the overall performance of the FBAR.

The physical structure of an FBAR, including the substrate, piezoelectric layer, and electrodes, can form a cavity that supports standing electromagnetic waves. If the lateral dimensions of the FBAR or the spacing between layers are on the order of the EM wavelength (or a significant fraction of it), they can support EM resonance modes. Resonators are driven by applying an AC voltage across the piezoelectric layer, which generates an alternating electromagnetic field. This field can interact with the structure of the resonator and its surroundings, leading to EM cavity resonance. The pattern and placement of the electrodes can create regions where electromagnetic fields can resonate. These fields can reflect between the electrodes and the boundaries of the device, forming standing waves.

Spurious signals typically result from the fundamental piezoelectric resonance frequency of the FBAR resonator interacting with the EM cavity resonance frequency inside the resonator. This leads to complex physical field coupling and mixing near the filter resonance frequency, resulting in sub-spurious modes. Distinguished from spurious modes caused by lateral resonance, sub-spurious refer to spurious modes resulting from the lateral resonances interacting with the resonator's EM resonances, resulting in mixing products creating the sub-spurious modes. Sub-spurious modes typically appear at frequencies lower or higher than the primary resonance frequency and its harmonics but are not harmonically related. The EM resonance interacting with the acoustic resonance is supposed to have a mixture product of sub-spurious modes, due to the resonator's spurious lateral mode interacting with the resonator's EM resonances, resulting in mixing products of sub-spurious modes.

Therefore, the suppression of spurious signals can be achieved by modifying the characteristics of the EM cavity resonance of the FBAR resonator. This can be achieved by keeping the fundamental piezoelectric resonance frequency of the resonator constant and shifting the EM cavity resonance to a lower frequency. According to an embodiment of the present invention, the conventional FBAR resonator is modified to include a “zipper” edge top electrode having a series of local ridges/peaks and valleys generally between adjacent ridges or peaks 812. The ridges and valleys of the zipper edge top electrode act to increase the effective resonance length of the top electrode, thereby altering the frequency response characteristics of the EM cavity resonance of the FBAR resonator.

This shift of the EM cavity resonance frequency ensures that the sub-spurious signals generated from the interaction between the piezoelectric resonance frequency and the EM cavity resonance frequency, are shifted to a lower-frequency, which advantageously lies in a rejection band area outside the passband of the piezoelectric resonance. This effectively suppresses the spurious signals which may otherwise appear in the pass band.

The above-described new approach of an embodiment of the present invention is quite different and an advance from the traditional theory that lateral resonances generate spurious signals. Instead, according to an embodiment of the present invention, it is understood that the coupling and mixing of multiple physical fields between piezoelectric resonance and EM cavity resonance produce spurious signals, which better aligns with the real working principles and phenomena of FBAR resonators. This novel approach of an embodiment of the present invention provides a more effective framework for suppressing spurious signals in FBAR resonators, especially for UHF products.

An effective solution for suppressing spurious signals in FBAR resonators according to an embodiment of the present invention is based on addressing the mechanism of spurious signal generation through the multi-physical field coupling and mixing of the piezoelectric resonance with the EM cavity resonance. By modifying the characteristics of the EM cavity resonance—specifically—moving the cavity resonance to a lower frequency shifts the sub-spurious signal products of the multi-physical field coupling and mixing outside of the filter passband of the piezoelectric resonance to a lower-frequency which corresponds to the rejection band area beyond the series resonance frequency Fs, effectively suppressing spurious signals.

### DESCRIPTION OF THE DRAWINGS

The present disclosure will be understood and better appreciated from the following detailed description taken in conjunction with the drawings. Identical structures, elements or parts, which appear in more than one figure, are generally labeled with the same or similar number in all the figures in which they appear, wherein:

FIG. 1 is a perspective view of an FBAR resonator;

FIG. 2 is a perspective view of an FBAR resonator illustrating an active area;

FIG. 3 is a cross-section view of an FBAR resonator;

FIG. 4 is a cross-section view of an FBAR resonator;

FIG. 5 is an illustration of a prior art FBAR resonator;

FIG. 6 is a plot of impedance as a function of frequency for a prior art FBAR resonator;

FIG. 7 is a plot of phase response as a function of frequency for a prior art FBAR resonator;

FIG. 8 is an illustration of an FBAR resonator according to an embodiment of the present invention;

FIG. 9 is a plot of impedance as a function of frequency for an FBAR resonator according to an embodiment of the present invention;

FIG. 10 is a plot of phase response as a function of frequency for an FBAR resonator according to an embodiment of the present invention and

FIG. 11 is a block diagram of an FBAR filter according to an embodiment of the present invention.

### DETAILED DESCRIPTION OF THE INVENTION

In the following detailed description, numerous specific details are set forth in order to provide a thorough understanding of the invention. However, it will be understood by those skilled in the art that the present invention may be practiced without some of those specific details. In other instances, well-known methods, procedures, and components have not been described in detail so as not to obscure the present invention.

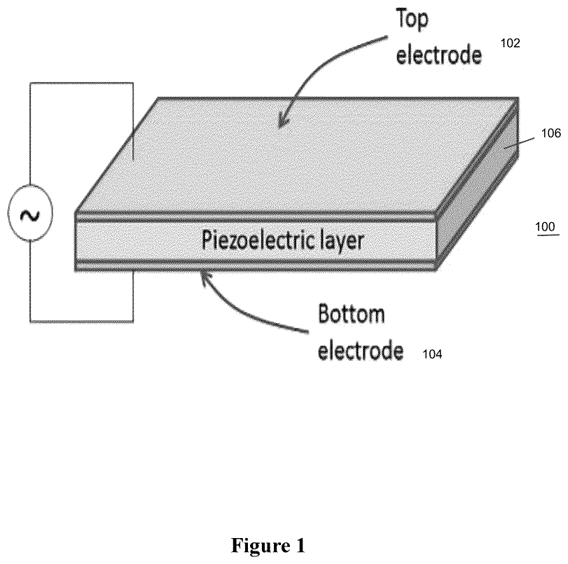

Referring now to FIG. 1, therein is illustrated an FBAR resonator 100. The FBAR 100 may include a top electrode 102 positioned generally parallel to and above a bottom electrode 104. In between the electrodes is a piezoelectric layer 106. The electrodes may be generally the same size, or alternatively, one electrode may be larger than the other. Also, in an embodiment, the first electrode may be larger than the second electrode. Similarly, the piezoelectric layer may be the same size as one or both of the electrodes, or alternatively, the piezoelectric layer may be larger than one or both of the electrodes. The electrodes may be formed using molybdenum (Mo), ruthenium (Ru), tungsten (W) or titanium tungsten (TiW).

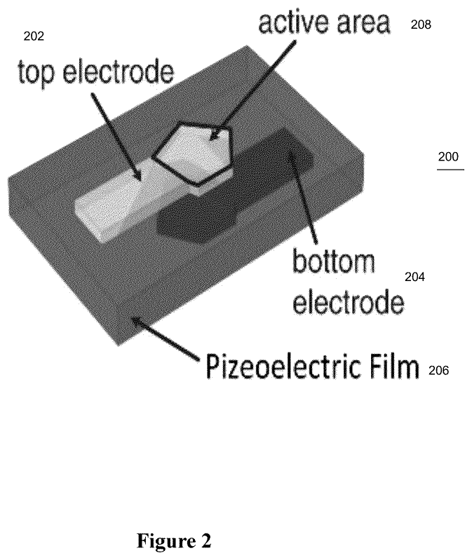

Referring now to FIG. 2, therein is illustrated a perspective view of an FBAR resonator 200. The FBAR includes a top electrode 202, bottom electrode 204, and piezoelectric film 206. The area of overlap between top electrode 202 and bottom electrode 204 results in an active area 208, where the signal resonance primarily takes place.

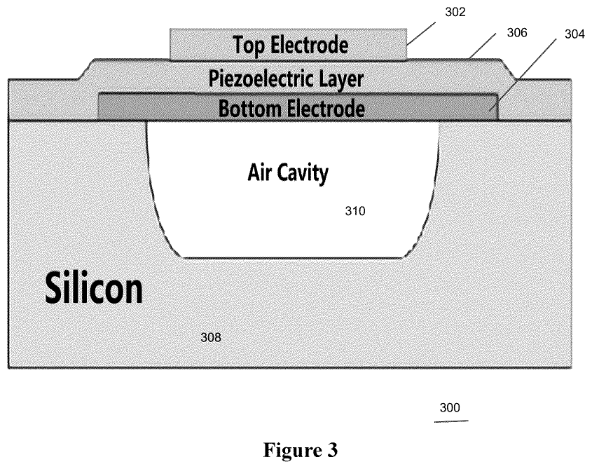

Referring now to FIG. 3, therein is illustrated a cross-sectional view of an FBAR resonator 300. The FBAR 300 includes a top electrode 302, bottom electrode 304, and piezoelectric layer 306 between the two electrodes 302, 304. The electrodes 302, 304 and piezoelectric layer 306 are formed on a semiconductor substrate, such as Silicon 308. Formed into the Silicon 308 and below the bottom electrode is an air cavity 310. The air cavity 310 beneath the resonator acts as an acoustic reflector, minimizing the transmission of acoustic energy into the substrate. This reduces acoustic losses and enhances the quality factor (Q-factor) of the resonator. Without an air cavity 310, acoustic waves can couple into the substrate, leading to energy dissipation and unwanted resonances. The air cavity 310 prevents this coupling, ensuring that the acoustic energy remains confined within the resonating structure.

The air cavity 310 allows for the formation of standing acoustic waves within the resonator. This is essential for achieving clear and distinct resonances at specific frequencies. By providing an effective acoustic isolation, the air cavity 310 helps achieve a higher Q-factor, which is crucial for the resonator's performance in filtering and frequency control applications.

The air cavity 310 also affects the effective thickness of the resonating structure. Changes in the air cavity 310 dimensions can be used to fine-tune the resonant frequency of the FBAR. The presence of an air cavity 310 ensures that the resonant frequency is less sensitive to external mechanical or thermal disturbances, contributing to frequency stability.

The air cavity 310 also provides mechanical isolation from the substrate 308, reducing the impact of substrate vibrations and mechanical stresses on the resonator's performance. By minimizing mechanical coupling, the air cavity 310 helps improve the long-term reliability and durability of the resonator, particularly in harsh operating conditions.

The air cavity 310 acts as a thermal barrier, reducing the thermal conductivity between the resonator and the substrate 308. This can help manage the thermal stability of the resonator and mitigate thermal-induced frequency shifts. By providing thermal isolation, the air cavity 310 allows the FBAR to maintain consistent performance even in high-temperature environments.

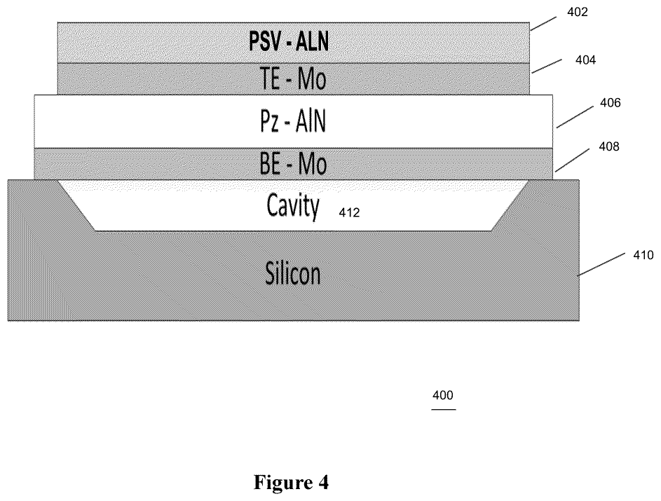

Referring now to FIG. 4, therein is illustrated another cross-sectional view of an FBAR resonator 400. As shown, the FBAR 400 includes top electrode 404 and bottom electrode 408, which may be formed of Mo (molybdenum). In between the electrodes 404, 408 is the piezoelectric film 406, which may be formed of aluminum nitride AlN, Sc(x) Al(1-x)N, Ba(x)Sr(1-x)TiO3, LiNbO3, or LiTaO3. The piezoelectric layer may be formed using single crystal material. Additionally, a passivation layer 402 may be formed above the top electrode 404, and may be formed of aluminum nitride AlN material.

FWHM typically refers to Full Width at Half Maximum. It is a measure used to describe the width of a peak in a distribution. Specifically, FWHM is the width of the peak at half of its maximum intensity. A lower FWHM value indicates a sharper peak, which corresponds to a higher degree of crystallinity and fewer defects in the crystal structure. In the piezoelectric layer, a FWHM value of less than 1 degree indicates that the layer has a very high crystalline quality with minimal structural imperfections.

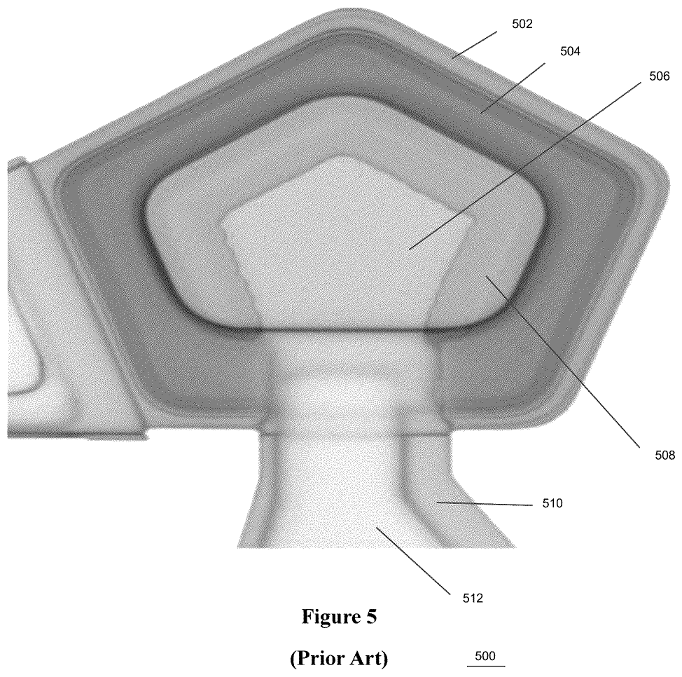

FIG. 5 illustrates the layout of a conventional FBAR resonator 500. As shown in FIG. 5, the FBAR resonator 500 includes a top electrode 506, bottom electrode 502, and piezoelectric film 504 in between the top and bottom electrodes. The FBAR resonator 500 also includes a via 508 for contacting the piezoelectric film 504, as well as a top electrode 510 and a contact pad 512 for contacting the top electrode 506.

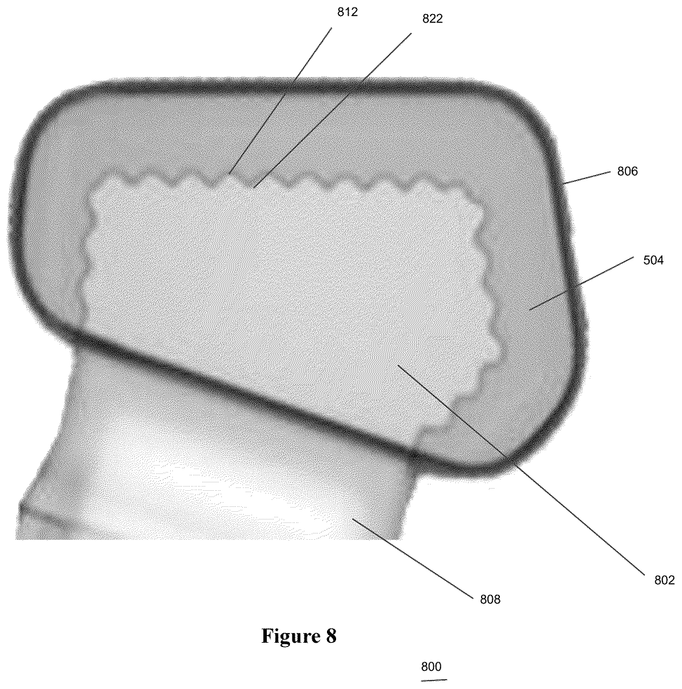

According to an embodiment of the present invention as illustrated in FIG. 8, the conventional FBAR resonator 500 in FIG. 5 is modified to include a “zipper” edge top electrode 802 as part of resonator 800. The zipper edge top electrode 802 includes a series of local ridges or peaks 812 and valleys 822, with the valleys 822 being generally between adjacent ridges or peaks 812. The ridges and valleys of the zipper edge top electrode 802 act to increase the effective resonance length of the top electrode 802, thereby altering the frequency response characteristics of the EM cavity resonance of the FBAR resonator 800. The ridges or peaks 812 and valleys 822 may be uniform in height and/or spacing, or they may be nonuniform, with some ridges 812 higher than others, or some ridges 812 being wider than others. Additionally, some of the valleys 822 may be lower than others, or some valleys 822 may be wider than others. The resonator 800 also includes a via 804 for the piezoelectric film. The resonator 800 also includes an edge 806 between the island and the via 804 for the piezoelectric film. Additionally, the resonator 800 includes a pad (e.g., Au) 808 for contacting the top electrode 802. In an embodiment of the invention, an objective of the ridges and valleys is to increase the effective resonance length of the electrode. This may be achieved by creating a non-smooth or non-uniform edge profile of the electrode.

In various embodiments according to the present invention, the “zipper” edge may be provided on only a portion of the top electrode, or it may be provided on the entirety of the top electrode. In yet another alternative, the “zipper” edge may be provided in selected areas of the top electrode, with the areas in between the “zipper” edge having a conventional smooth edge. Additionally, in various embodiments, the various versions of the “zipper” edge described herein may be provided as part of the bottom electrode. In yet other embodiments, the various versions of the “zipper” edge described herein may be provided on both of the top and bottom electrodes.

The frequency response of the EM cavity resonance of an FBAR resonator is determined generally by the following relationship:

$${f}_{mn} = \frac{c}{2} \sqrt{{( \frac{m}{a} )}^{2} + {( \frac{n}{b} )}^{2} + {( \frac{p}{d} )}^{2}}$$

where c is the speed of light, a, b, and d are the dimensions of the cavity in the x, y, and z directions, and m, n, and p are the mode numbers in the x, y, and z directions, respectively. Mode numbers generally refer to different EM resonances.

Due to the longer length introduced by the zipper edge top electrode 802, the cavity resonance frequency is shifted to a lower frequency. However, for the piezoelectric resonance characteristics of the FBAR resonator, the zipper edge top electrode 802 is substantially equivalent to a conventional smooth edge electrode and has almost the same resonator area. The piezoelectric resonance frequency of the FBAR resonator is generally determined by the following relationship:

$${f}_{0} = \frac{1}{2 π} \sqrt{\frac{k}{m}}$$

The resonance frequency, f₀, is a function of the total mass m of the FBAR resonator and the stiffness k of the piezoelectric film material. The area of the electrodes influences the mass of the electrodes, contributing to the overall effective mass of the FBAR resonator. As can be seen from the above relationship, increasing the FBAR resonator mass m will lower the resonance frequency f₀. Conversely, increasing the overall stiffness k of the piezoelectric film will act to increase the resonance frequency f₀.

Hence, the fundamental piezoelectric resonance frequency remains unchanged with the introduction of the zipper edge top electrode 802. This is due to the fact that the introduction of the zipper edge will not change the top electrode area, while the corresponding mass and stiffness do not change as well. Thus, the fundamental piezoelectric resonance frequency remains substantially unchanged.

However, due to the lower shift of the cavity resonance frequency, the sub-spurious signals or modes (a mixture produced by the EM resonance interacting with the acoustic resonance) resulting from the multi-physical field coupling and mixing inside the resonator are shifted outside the passband of the piezoelectric resonance to a lower-frequency rejection band area below the series resonance frequency F₀, effectively suppressing spurious signals. The resonator fundamental piezoelectric resonance does not change, while the resonator's EM resonance shifts to a lower frequency due to the zipper edge effect. Thus, the mixing products shift to lower frequencies, outside the pass band, but within the suppression band of the filter.

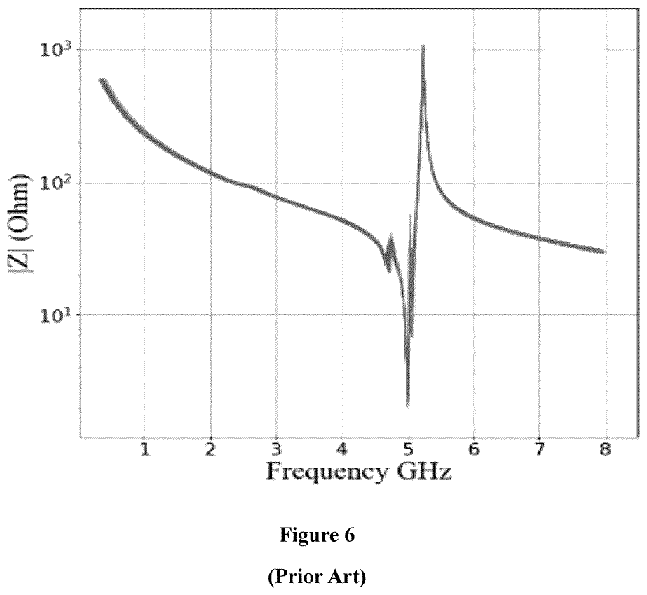

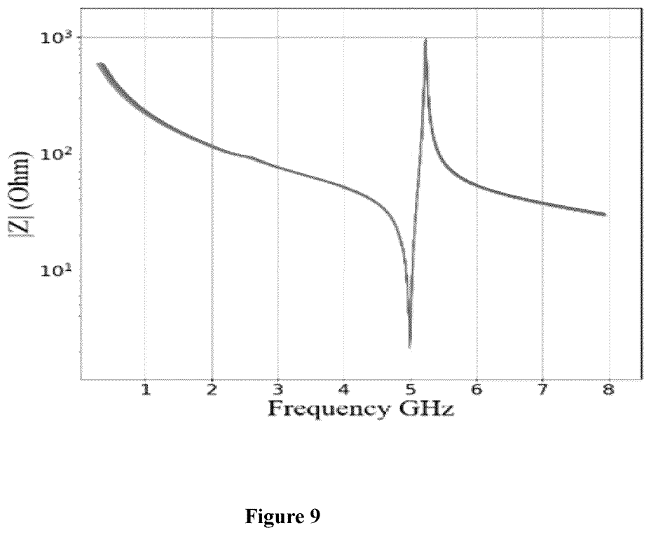

Referring now to FIG. 6, therein is illustrated a plot of the impedance of the resonance as a function of frequency for a conventional FBAR resonator, such as illustrated in FIG. 5. Conversely, FIG. 9 illustrates a similar plot of impedance as a function of frequency for the “zipper edge” top electrode according to an embodiment of the present invention, such as illustrated in FIG. 8. As shown in FIGS. 6 and 9, it can be seen that the impedance plot of FIG. 6 displays two distinct peaks: one sharp peak and one less pronounced peak around 5 GHz. The sharp peak suggests a strong resonance, indicating a high Q-factor for this mode. The additional smaller peaks or perturbations indicate spurious resonances

In contrast, the impedance plot of FIG. 9 displays a single sharp peak around 5 GHZ, similar to FIG. 6, but with a cleaner profile without any additional, lesser pronounced peaks. The single sharp peak still indicates a strong resonance with a high Q-factor. However, there are fewer additional, lesser pronounced peaks or perturbations, suggesting less spurious resonances

An effective solution resulting from the zipper edge and its suppression of spurious resonances is based on addressing the mechanism of spurious signal generation through the multi-physical field coupling and mixing of the piezoelectric resonance with the EM cavity resonance. By the zipper edge modifying the characteristics of the EM cavity resonance, specifically, moving the cavity resonance to a lower frequency, results in shifting the sub-spurious signal products of the multi-physical field coupling and mixing outside of the filter passband of the piezoelectric resonance to a lower-frequency which corresponds to the rejection band area beyond the series resonance frequency Fs, effectively suppressing spurious signals.

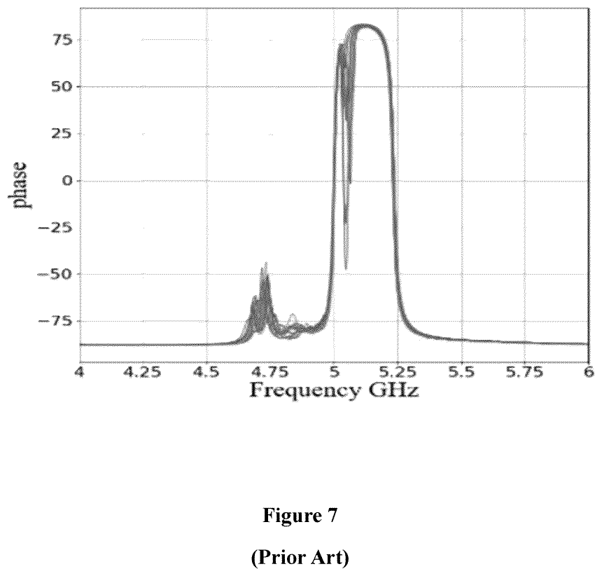

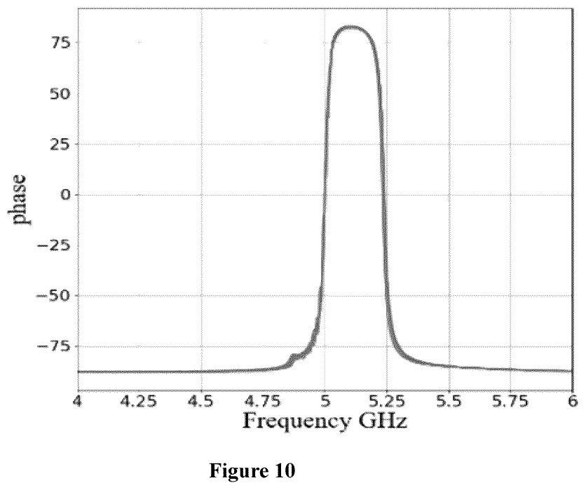

Referring now to FIG. 7, therein is illustrated a plot of the phase response of the resonance as a function of frequency for a conventional FBAR resonator, such as illustrated in FIG. 5. Conversely, FIG. 10 illustrates a similar plot of phase response as a function of frequency for the “zipper edge” top electrode according to an embodiment of the present invention, such as illustrated in FIG. 8. As shown in FIGS. 7 and 10, it can be seen that the phase response plot of FIG. 7 has two distinct spurs, one sharp spur and one less pronounced spur around 4.75 GHz. The sharp spur suggests a strong phase discontinuity, indicating a spurious resonance within the passband. The additional smaller spurs indicate spurious resonances at lower frequencies. In contrast, FIG. 10 illustrates a much cleaner phase response profile, indicating that there are far fewer spurious resonances.

Compared to the traditional “smooth” raised frame electrodes, which introduce other spurious signals in the low-frequency range (for example, in the range of 4.75 GHZ), the resonant response curve of the FBAR resonator with zipper edge top electrode is substanitally smooth, effectively suppressing spurious signals and improving the overall performance of the FBAR filter. The zipper edge may be implemented as part of either a top electrode or a bottom electrode of the FBAR resonator. Alternatively, the zipper edge may be implemented as part of both top and bottom electrodes. Additionally, the zipper edge may be implemented along an entire edge portion of one of the electrodes, or may be implemented along a section of the edge portion of one of the electrodes, i.e., not extending along an entire periphery of the electrode. In yet another alternative, the zipper edge may be implemented along multiple sections of an electrode, with smooth edge portions in between the zipper edge portions.

Additionally, the zipper edge top electrode does not require a raised frame, which reduces processing equipment and process control requirements, resulting in lower production costs and higher yields. In an embodiment, the present invention provides an innovative and effective solution for spurious suppression in FBAR resonators with great practical value and application prospects.

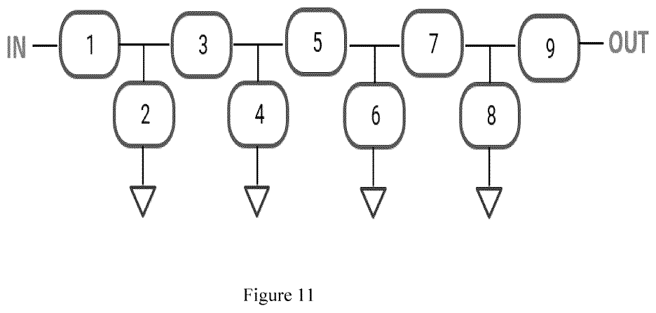

Referring now to FIG. 11, therein is illustrated a block diagram of a ladder filter 1100 constructed using FBAR resonators according to an embodiment of the present invention. The illustrated ladder filter 1100 includes an input IN and an output OUT. In between the input and output are arranged a number of series connected FBAR resonators, illustrated as 1, 3, 5, 7, and 9. The specific number of series connected resonators may be more or maybe less than what is illustrated, and may be selected based on the desired filter and filter characteristics to be obtained. In between each pair of series connected resonators is a parallel connected resonator, illustrated as 2, 4, 6, and 8. The specific number of parallel connected resonators may be more or maybe less than what is illustrated, and may be selected based on the desired filter and filter characteristics to be obtained. Each parallel connected resonator has a first node which is connected between two series connected resonators, as well as a second node connected to ground. In a single stage filter which may have a single series connected resonator, then the parallel connected resonator would have its first node connected to the OUT output of the filter. In a ladder filter for electronic signals, the series resonators provide the passband allowing desired frequencies to pass through. The parallel resonators create notches at specific frequencies to block unwanted signals, thereby enhancing the performance of the filter in terms of selectivity and insertion loss. This combination of series and parallel resonators forms the “rungs” and “steps” of a ladder filter, giving it its characteristic name and functionality.

It should be appreciated that the above-described methods and apparatus may be varied in many ways, including omitting or adding elements or steps, changing the order of steps and the type of devices used. It should be appreciated that different features may be combined in different ways. In particular, not all the features shown above in a particular embodiment are necessary in every embodiment of the invention. Further combinations of the above features are also considered to be within the scope of some embodiments of the disclosure.

It will be appreciated by persons skilled in the art that the present invention is not limited to what has been particularly shown and described hereinabove. Rather the scope of the present invention is defined only by the claims, which follow.

1. A bulk acoustic resonator comprising:
a first electrode having a first planar portion;
a second electrode having a second planar portion disposed substantially parallel to the first planar portion;
and a piezoelectric layer disposed between and contacting both the first and second planar portions;
wherein at least a portion of an edge of one of the electrodes is formed with a plurality of peaks and valleys which are operable to increase an effective resonance length of the electrode, thereby altering a frequency response characteristic of an electromagnetic resonance of the resonator.

2. The bulk acoustic resonator of claim 1, wherein the plurality of peaks and valleys are formed along substantially an entire length of one electrode.

3. The bulk acoustic resonator of claim 1, wherein the plurality of peaks and valleys are formed along a portion of both the first and second electrodes.

4. The bulk acoustic resonator of claim 1, further comprising an air cavity under the first electrode and on top of the second electrode to thereby create a Film Bulk Acoustic Resonator (FBAR).

5. The bulk acoustic resonator of claim 4, where the electromagnetic resonance created by the air cavity under the first electrode is shifted to a lower resonance frequency.

6. The bulk acoustic resonator of claim 1 where the piezoelectric layer is selected from the group consisting of AlN, Sc(x)Al(1-x)N, Ba(x)Sr(1-x)TiO3, LiNbO3, and LiTaO3.

7. The bulk acoustic resonator of claim 5 where the piezoelectric layer has a FWHM value of less than 1 degree.

8. The bulk acoustic resonator of claim 5 where the piezoelectric layer is formed using single crystal material.

9. The bulk acoustic resonator of claim 1 wherein the first electrode is larger than the second electrode.

10. The bulk acoustic resonator of claim 1 where the piezoelectric layer is larger than the first electrode.

11. The bulk acoustic resonator of claim 1 where the first and second electrode layers are formed using material selected from the group consisting of Mo, Ru, W and TiW.

12. The bulk acoustic resonator of claim 1, wherein the first electrode is a top electrode and the peaks and valleys are formed as part of the top electrode.

13. The bulk acoustic resonator of claim 1, wherein the peaks are substantially uniform in height.

14. The bulk acoustic resonator of claim 1, wherein the peaks are substantially uniform in width.

15. The bulk acoustic resonator of claim 1, wherein the valleys are substantially uniform in height.

16. The bulk acoustic resonator of claim 1, wherein the valleys are substantially uniform in width.

17. An electronic signal filter having an input and an output, the filter comprising:
at least one series connected resonator having a first node connected to the filter input and a second node connected to the filter output;
at least one parallel connected resonator having a first node connected to the second node of the series connected resonator and a second node connected to ground;
wherein each of the series connected resonator and the parallel connected resonator further comprise a first electrode having a first planar portion, a second electrode having a second planar portion disposed substantially parallel to the first planar portion;
and a piezoelectric layer disposed between and contacting both the first and second planar portions, wherein at least a portion of an edge of one of the electrodes is formed with a plurality of peaks and valleys which are operable to increase an effective resonance length of the electrode, thereby altering a frequency response characteristic of an electromagnetic resonance of the resonator.

18. An electronic signal filter having an input and an output, the filter comprising:
a plurality of series connected resonators, a first resonator of the plurality having a first node connected to the filter input and a last of the series connected resonators having a second node connected to the filter output;
a plurality of parallel connected resonators, each of the parallel connected resonators having a first node connected in between two of the series connected resonators, each of the parallel connected resonators having a second node connected to ground;
wherein each of the series connected resonators and the parallel connected resonators further comprise a first electrode having a first planar portion, a second electrode having a second planar portion disposed substantially parallel to the first planar portion;
and a piezoelectric layer disposed between and contacting both the first and second planar portions, wherein at least a portion of an edge of one of the electrodes is formed with a plurality of peaks and valleys which are operable to increase an effective resonance length of the electrode, thereby altering a frequency response characteristic of an electromagnetic resonance of the resonator.

19. The filter of claim 18, wherein the plurality of peaks and valleys are formed along substantially an entire length of one electrode.

20. The filter of claim 18, wherein the plurality of peaks and valleys are formed along a portion of both the first and second electrodes.

21. The filter of claim 18, wherein the peaks are substantially uniform in height.

22. The filter of claim 18, wherein the peaks are substantially uniform in width.

23. The filter of claim 18, wherein the valleys are substantially uniform in height.

24. The filter of claim 18, wherein the valleys are substantially uniform in width.
